(19) United States
(12) Patent Application Publication
(10) Pub. No.: US 2020/0006122 A1
(43) Pub. Date: Jan. 2, 2020

(54) INTEGRATED CIRCUITS (ICS) MADE USING EXTREME ULTRAVIOLET (EUV) PATTERNING AND METHODS FOR FABRICATING SUCH ICS

(71) Applicant: QUALCOMM Incorporated, San Diego, CA (US)

(72) Inventors: Mustafa Badaroglu, Kessel-Lo (Leuven) (BE); Kern Rim, San Diego, CA (US)

(21) Appl. No.: 16/020,096

(22) Filed: Jun. 27, 2018

(51) Int. Cl. H01L 21/768; H01L 21/033; H01L 23/528; H01L 21/311

(52) U.S. Cl. CPC H01L 21/76816; H01L 21/0332; H01L 21/31144; H01L 23/5286; H01L 23/5283; H01L 21/0337

(57) ABSTRACT

Integrated circuits (ICs) made using extreme ultraviolet (EUV) patterning and methods for fabricating such ICs are disclosed. In an exemplary aspect, fabricating such ICs includes using a double-exposure EUV process when making metal trenches for the ICs. In particular, after a first EUV exposure and etching process, spacers are used before a second EUV exposure to guarantee minimum spacing between the metal trenches.

### BACKGROUND

### I. Field of the Disclosure

The technology of the disclosure relates generally to integrated circuits (ICs) fabricated using extreme ultraviolet (EUV) patterning and methods for fabricating ICs using EUV patterning.

### II. Background

Integrated circuits (ICs) are critical components in almost all modern computing devices. Transistors are commonly employed in ICs. One common transistor type in an IC is a Field-Effect Transistor (FET) and, more specifically, a metal oxide semiconductor (MOS) FET (MOSFET). As electronic devices become more complex in functionality, so does the need to include a greater number of transistors in such devices. Concurrently, there is pressure to provide the transistors in increasingly smaller sizes, particularly for portable devices such as smart phones. The increase in the number of transistors is achieved in part through continued efforts to miniaturize transistors in ICs. For example, critical sizes in ICs are being scaled down by a reduction in minimum metal line width in the ICs (e.g., 65 nanometers (nm), 45 nm, 28 nm, 20 nm, etc.). Current efforts have seen the critical size of FETs drop to and below 10 nm.

Recent efforts to improve critical size reduction have been focused on the use of extreme ultraviolet (EUV) lithography. EUV lithography relies on relatively expensive machines to expose the semiconductor wafers to a single dose of ultraviolet light (e.g., between 12 and 15 nm and, more particularly, around 13.5 nm). Current costs for such machines are in the range of one hundred fifty million US dollars 150,000,000). Initial efforts with EUV lithography returned low yields, which lead to an increase in the exposure time to increase dosing of the target. While extending exposure time increases yields to acceptable levels, each extension in the exposure time slows throughput for the foundry, and thus, to achieve a foundry-wide acceptable throughput, multiple ones of these machines (e.g., around twenty or more) may be required in the assembly line. Given the cost of these machines, the requirement for twenty or more such machines raises operating costs to burdensome levels, which in turn increases the cost for individual wafers. Accordingly, there is a need to improve EUV lithographic techniques to allow for acceptable throughput levels, acceptable yield levels, and still meet the critical size requirements.

### SUMMARY OF THE DISCLOSURE

Aspects disclosed in the detailed description include integrated circuits (ICs) made using extreme ultraviolet (EUV) patterning and methods for fabricating such ICs. In an exemplary aspect disclosed herein, fabricating such ICs includes using a double-exposure EUV process when making metal trenches for the ICs. In particular, after a first EUV exposure and etching process, spacers are used before a second EUV exposure to guarantee minimum spacing between the metal trenches.

The use of two EUV exposures instead of a single exposure actually reduces the total amount of time that an EUV emitter is required, which in turn improves throughput at a foundry relative to generally accepted single-exposure processes. This two-exposure process provides high yield results at a desired critical size less than sixteen nanometers (16 nm). Double patterning allows for self-aligned cutting where cuts are made in alternating fashion to avoid cutting adjacent lines while also allowing for reduced space between adjacent lines. Further, the use of the two exposures provides acceptably high yields with lower overall energy expenditures. Still further, the double-exposure process allows flexibility in patterning that provides critical sizes less than 16 nm while preserving minimum spacing requirements between metal trenches.

In this regard in one aspect, an IC is disclosed. The IC includes a substrate. The IC also includes an active element disposed on a first side of the substrate. The IC also includes a metal layer disposed above the active element on the first side of the substrate. The metal layer includes a metal trench. The metal trench includes a buffer zone. The buffer zone has a uniform outward dimension on two opposite sides of the metal trench.

In another aspect, an IC is disclosed. The IC includes a means for supporting active elements. The IC also includes a means for performing a function disposed on a first side of the means for supporting the active elements. The IC also includes a metal layer disposed above the means for performing the function on the first side of the means for supporting the active elements. The metal layer includes a metal trench. The metal trench includes a buffer zone. The buffer zone has a uniform outward dimension on two opposite sides of the metal trench.

In another aspect, a method of fabricating an IC is disclosed. The method includes forming a lithographic stack including a first resist and a lithographic material over a hard layer on a low-k dielectric material. The method also includes putting a first mandrel having a first pattern over the first resist. The method also includes exposing the first mandrel to a first EUV exposure to harden a first portion of the first resist and soften a second portion of the first resist. The method also includes etching the first resist and the lithographic material corresponding to the second portion to form a first void. The method also includes filling the first void with a first sacrificial material fill. The method also includes growing a first spacer around the first sacrificial material fill. The method also includes forming a second lithographic material around the first spacer and a second resist above the first spacer. The method also includes putting a second mandrel having a second pattern over the second resist. The method also includes exposing the second mandrel to a second EUV exposure to harden a first portion of the second resist and soften a second portion of the second resist. The method also includes etching the second resist and the second lithographic material corresponding to the second portion to form a second void. The method also includes filling the second void with a second sacrificial material fill. The method also includes etching the first sacrificial material fill and a first portion of the low-k dielectric material underneath the first sacrificial material fill to form a first trench guide. The method also includes etching the second sacrificial material fill and a second portion of the low-k dielectric material underneath the second sacrificial material fill to form a second trench guide. The method also includes filling the first trench guide and the second trench guide with a metal material to form metal trenches in the low-k dielectric material.

### BRIEF DESCRIPTION OF THE FIGURES

FIG. 1 is a simplified side elevational view of an exemplary integrated circuit (IC) manufactured according to exemplary aspects of the present disclosure showing metal layers which may be formed with the two-stage extreme ultraviolet (EUV) exposure processes outlined herein;

FIG. 2 is a simplified top plan view of a metal layer from the IC of FIG. 1 showing metal trenches with various widths and intermediate cuts while preserving minimum spacing therebetween that is enabled by aspects of the two-stage EUV processes of the present disclosure;

FIGS. 3A and 3B together are a flowchart illustrating an exemplary double EUV exposure process for fabricating the IC of FIG. 1 with metal trenches having minimum spacing guarantees as illustrated in FIG. 2;

FIGS. 4A-4V-2 are views of the IC at various steps of being fabricated according to the process of FIGS. 3A and 3B;

FIG. 5 is a top view of the IC during fabrication illustrating how using spacer material forces the creation of buffer space;

FIG. 6 is a top view of a metal layer of the IC showing metal trenches formed in the IC with minimum buffer space therebetween;

FIG. 7 is a block diagram of an exemplary processor-based system that can include the IC of FIG. 1; and

FIG. 8 is a block diagram of an exemplary wireless communications device that includes radio frequency (RF) components formed in an IC, that may be fabricated according to the process of FIGS. 3A and 3B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include integrated circuits (ICs) made using extreme ultraviolet (EUV) patterning and methods for fabricating such ICs. In an exemplary aspect disclosed herein, fabricating such ICs includes using a double-exposure EUV process when making metal trenches for the ICs. In particular, after a first EUV exposure and etching process, spacers are used before a second EUV exposure to guarantee minimum spacing between the metal trenches.

The use of two EUV exposures instead of a single exposure actually reduces the total amount of time that an EUV emitter is required, which in turn improves throughput at a foundry relative to generally accepted single-exposure processes. This two-exposure process provides high yield results at a desired critical size less than sixteen nanometers (16 nm). Double patterning allows for self-aligned cutting where cuts are made in alternating fashion to avoid cutting adjacent lines while also allowing for reduced space between adjacent lines. Further, the use of the two exposures provides acceptably high yields with lower overall energy expenditures. Still further, the double-exposure process allows flexibility in patterning that provides critical sizes less than 16 nm while preserving minimum spacing requirements between metal trenches.

Before addressing exemplary aspects of the present disclosure, a brief aside is provided relating to nomenclature. It should be appreciated that there are two types of “masks” used in semiconductor fabrication. A first type of mask is a hard element that is reused multiple times on multiple semiconductor wafers. A second type of mask, and the type of mask at issue in the present disclosure, is a mask that is formed within the components of the semiconductor wafer in a first process step so as to enable a second process step operating in a desired fashion. To the extent that the present disclosure uses the term “mask,” it is the second meaning that is intended, and the first meaning is designated by use of the term “mandrel.”

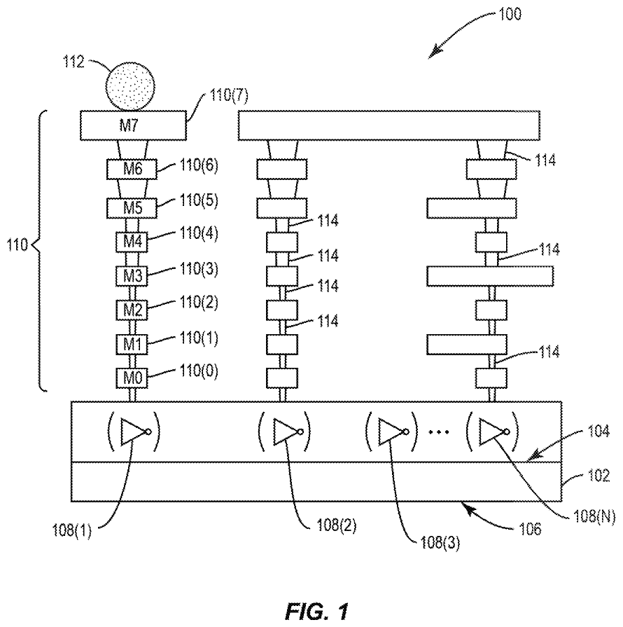

In this regard, FIG. 1 is simplified side elevational view of a cross-section of an exemplary integrated circuit (IC) 100 manufactured according to a two-stage EUV exposure process according to exemplary aspects of the present disclosure. The IC 100 includes a substrate 102, which may also be referred to as a means for supporting active elements. The substrate 102 may be a silicon material or the like as is well understood. The substrate 102 has a first or top side 104 (as opposed to the second or bottom side 106) on which active elements 108(1)-108(N) are disposed. The active elements 108(1)-108(N) may be logical functions such as AND, OR, NOR, NAND gates, buffers, flip-flops, or the like and may be formed from transistors, diodes, or the like as is well understood. As used herein an individual one of the active elements 108(1)-108(N) may also be referred to as a means for performing a function.

With continued reference to FIG. 1, a plurality of metal layers 110 and, more specifically, 110(0)-110(7) (sometimes referred to in the industry as M0-M7) are positioned “above” the active elements 108(1)-108(N). “Above” is a relative term, and as used in this context means that the plurality of metal layers 110 are positioned on the same side of the substrate 102 as the active elements 108(1)-108(N) (i.e., on the first or top side 104), with the active elements 108(1)-108(N) positioned between the plurality of metal layers 110 and the substrate 102. Thus, relative to the substrate 102, the plurality of metal layers 110 are “above” the active elements 108(1)-108(N). An uppermost metal layer 110(7) may be coupled to an external pin 112 to receive a signal, ground, a power supply, or the like as is well understood. While metal layers 110(0)-110(7) are illustrated, it should be appreciated that more or fewer metal layers may be present without departing from the scope of the present disclosure. While the present disclosure has illustrated the metal layers 110 as M0-M7, with M0 being the layer closest to the active elements 108(1)-108(N), some portions of the industry may refer to the layer closest to the active elements 108(1)-108(N) as M1 with no layer M0. While a specific nomenclature has been expressed in the present disclosure, exemplary aspects of the present disclosure are capable of use independent of such differences in nomenclature.

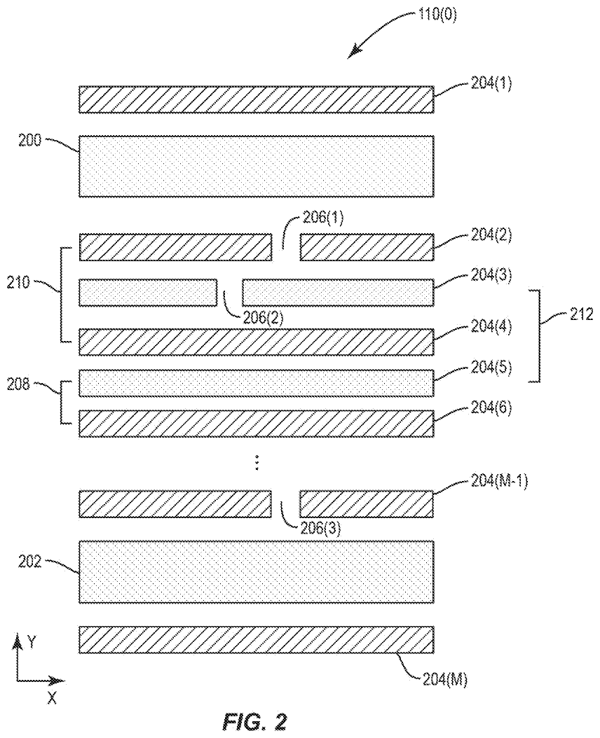

With continued reference to FIG. 1, the plurality of metal layers 110 allow interconnections between the active elements 108(1)-108(N) as well as provide power and ground rails (as better explained with reference to FIG. 2 below). While not explicitly illustrated, a dielectric material may fill the space between and around the plurality of metal layers 110. Vias 114 (sometimes referred to as vertical interconnect accesses) may vertically interconnect the plurality of metal layers 110.

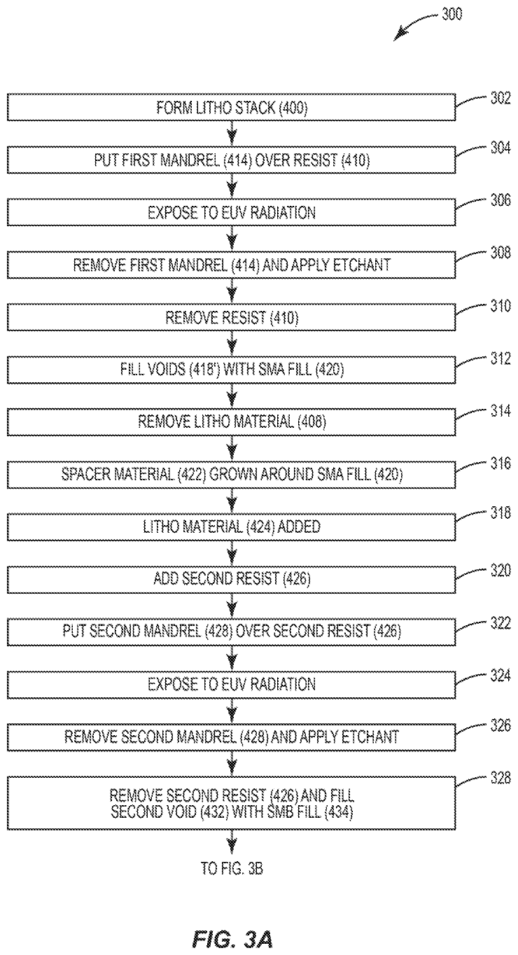

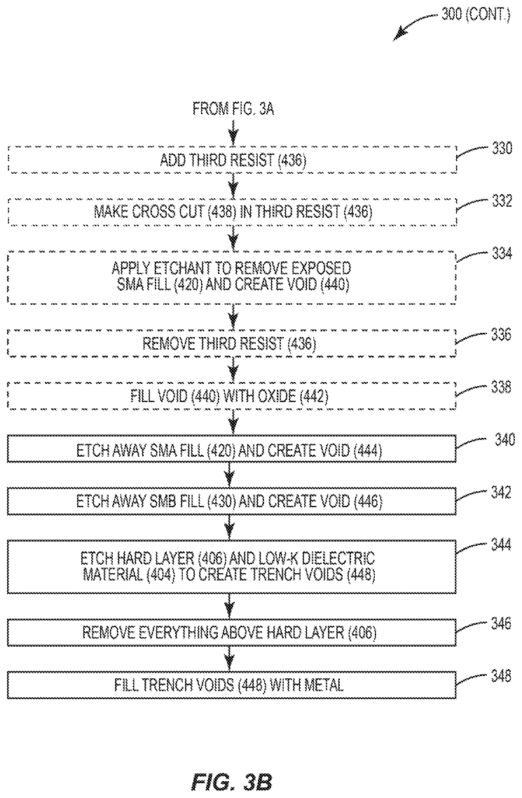

FIG. 2 is a simplified top plan view of a metal layer 110(0) from the IC 100 of FIG. 1 showing metal trenches with various widths and intermediate cuts enabled by aspects of the present disclosure. While the term metal trench is used throughout the present disclosure, it should be appreciated that equivalent terms are metal lines, metal traces, metal elements, conductors, or the like. Exemplary aspects of the present disclosure, and particularly process 300 set forth in FIG. 3, allow the metal trenches illustrated in FIG. 2 to be formed at a desired critical size (e.g., less than 16 nm, and more particularly, less than 10 nm) with suitable spacing between the metal trenches. Further, the use of a dual-exposure process allows self-aligned cutting to be performed so that cuts do not create improper shorts between adjacent metal trenches or improperly cut into adjacent metal trenches.

In particular, the metal layer 110(0) may include a metal trench 200 that is a power rail and a metal trench 202 that is a ground rail. Further metal trenches 204(1)-204(M) operate as signaling trenches and help effectuate interconnections between the active elements 108(1)-108(N) and the like within the IC 100. As illustrated, the metal trenches 200, 202, and 204(1)-204(M) are parallel along a longitudinal axis (i.e., the x-axis). Various cuts 206(1)-206(3) are present in one or more of the metal trenches 204(1)-204(M). Exemplary aspects of the present disclosure allow the lateral dimension (i.e., the width or the y-axis dimension) of the metal trenches 200, 202, and 204(1)-204(M) to be varied depending on the need. For example, to reduce voltage drop for the power rail 200, the width of the power rail 200 may be wider than the width of the metal trenches 204(1)-204(M).

It should be appreciated that the use of a self-aligned dual-exposure process relaxes the difficulty of positioning adjacent metal trenches in close proximity That is, the first exposure helps create the structures which are used to make one set of metal trenches and the second exposure helps create the structures which are used to make a second, interleaved set of metal trenches. In an exemplary aspect, the metal trenches 204(1), 204(2), 204(4), 204(6) . . . 204(M−1), and 204(M) are made using structures created by a first exposure (designated by the diagonal line hatching) and the interleaved metal trenches 200, 204(3), 204(5) . . . and 202 are made using structures created by a second exposure (designated by the dotted hatching). By interleaving the metal trenches in this manner, the individual mid-line to mid-line distance between metal trenches (i.e., the pitch) is greater than it would be if a single mask had been used to create the structures for all the metal trenches at once. As illustrated, a pitch 208 between adjacent metal trenches 204(5) and 204(6) is half the distance of a pitch 210 between metal trenches 204(2) and 204(4) or a pitch 212 between metal trenches 204(3) and 204(5). For example, if the pitch 210 is 10 nm, then the pitches 210 and 212 would be 20 nm and the masks used to create the exposures only have to comply with the less rigorous 20 nm pitch. Such relaxed positioning requirement allows for pitches less than 10 nm to be made more readily. Still further, by using appropriate spacers, the width of the metal trenches 200, 202, and 204(1)-204(M) may be varied, and even with the variation in the width of the metal trenches 200, 202, and 204(1)-204(M), exemplary aspects of the present disclosure provide a minimum guaranteed space between the metal trenches 200, 202, and 204(1)-204(M) as better explained in greater detail below. Likewise, exemplary aspects of the present disclosure provide a minimum tip-to-tip distance for the cuts 206(1)-206(3) without cutting adjacent metal trenches 204 (e.g., the cut 206(1) only cuts metal trench 204(2), not 200 or 204(3)).

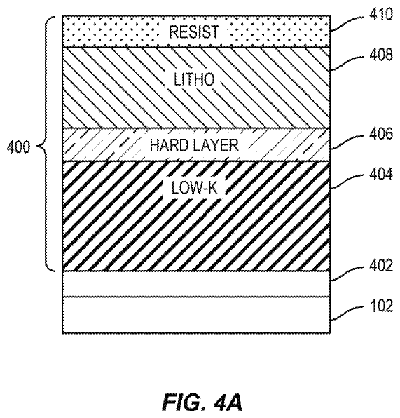

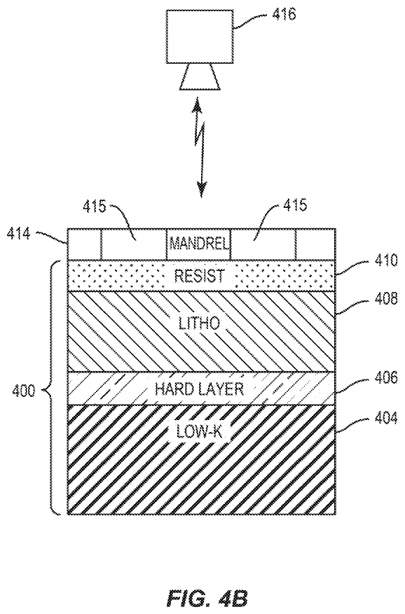

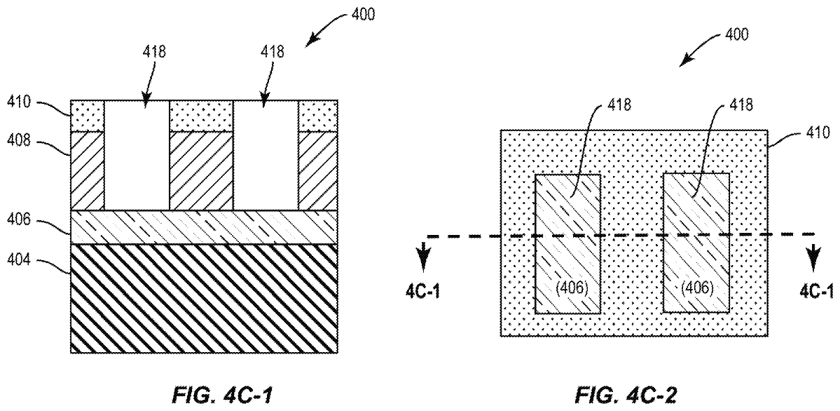

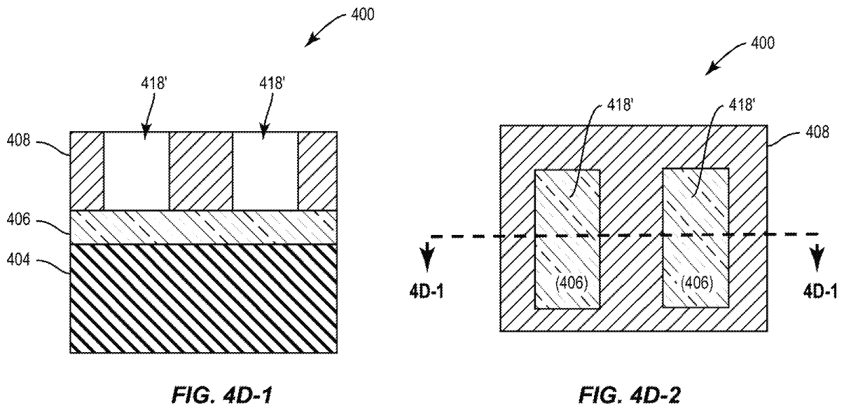

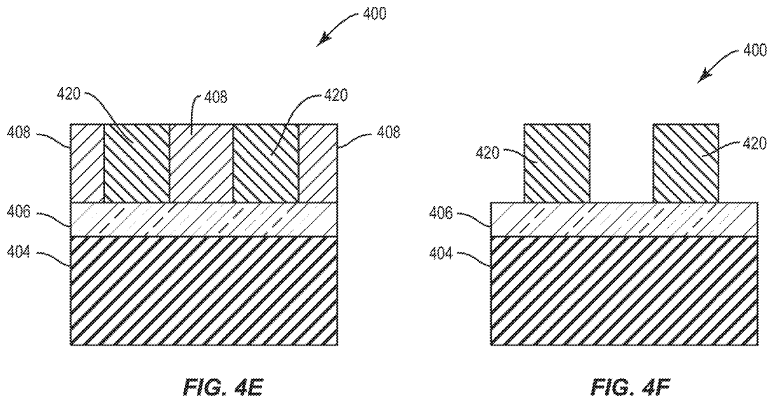

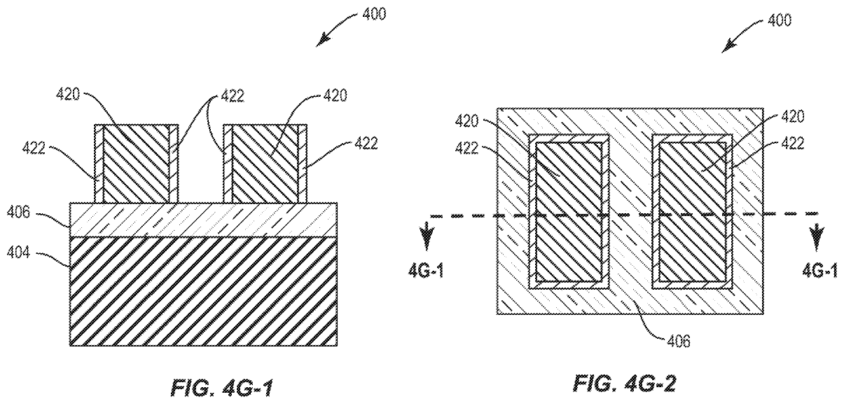

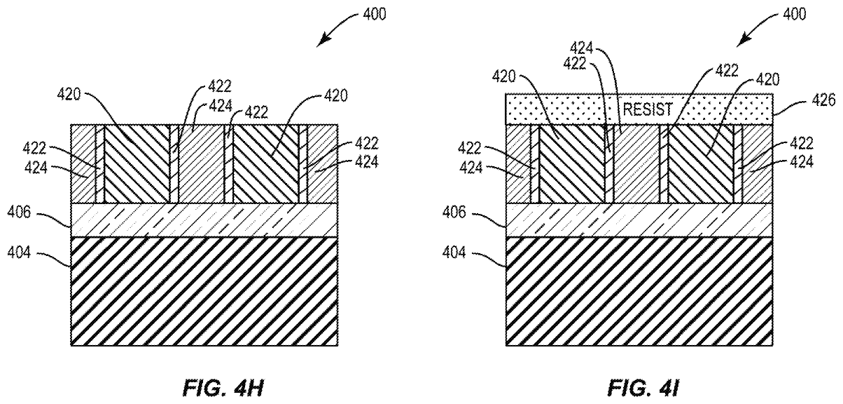

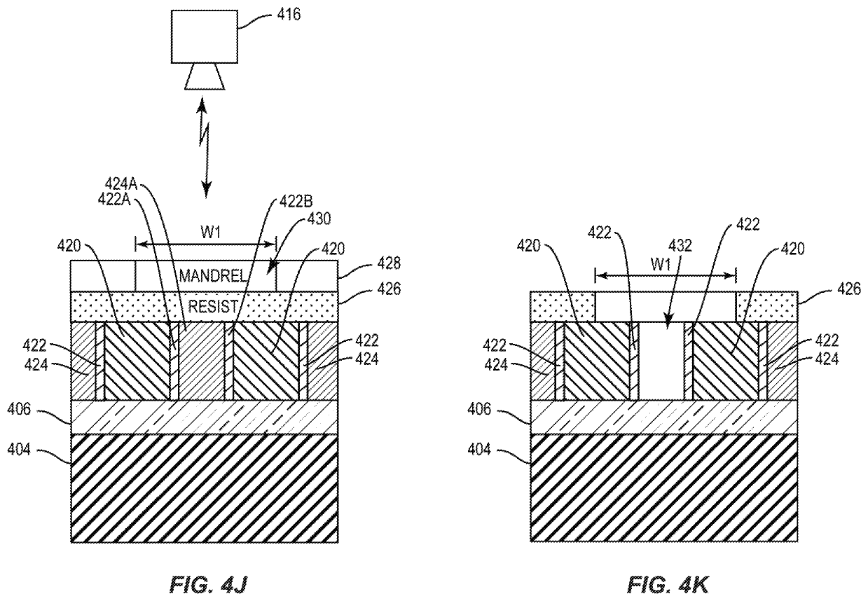

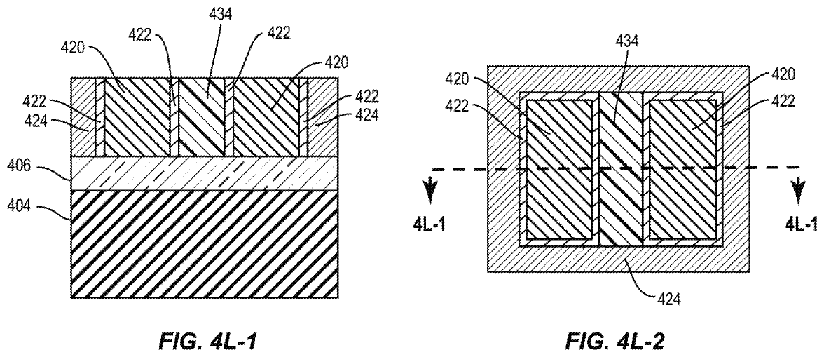

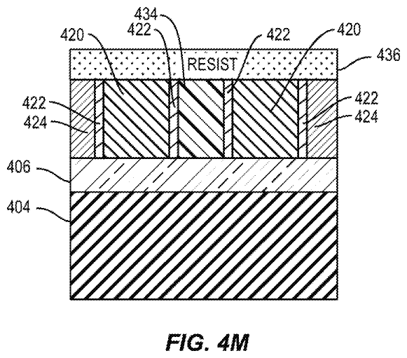

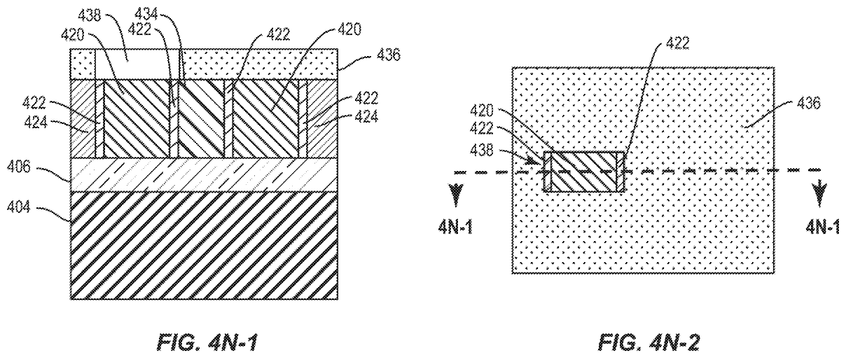

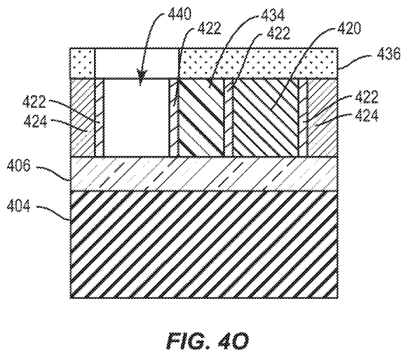

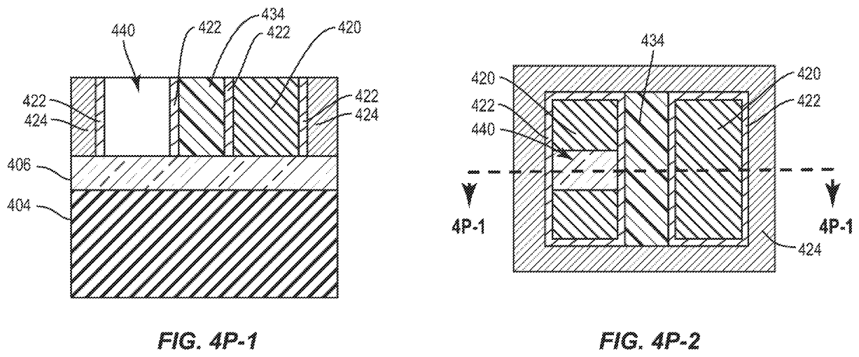

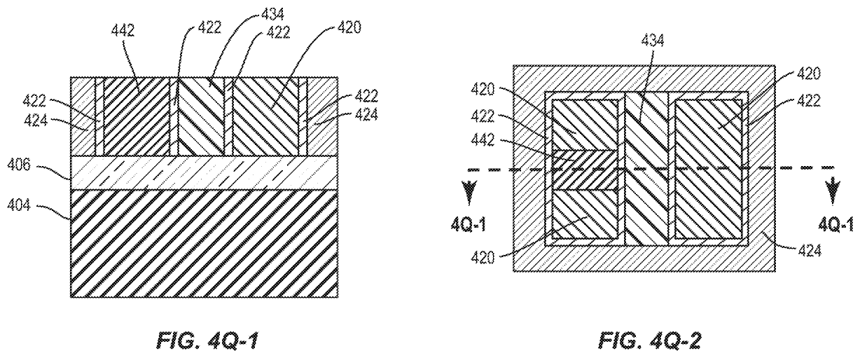

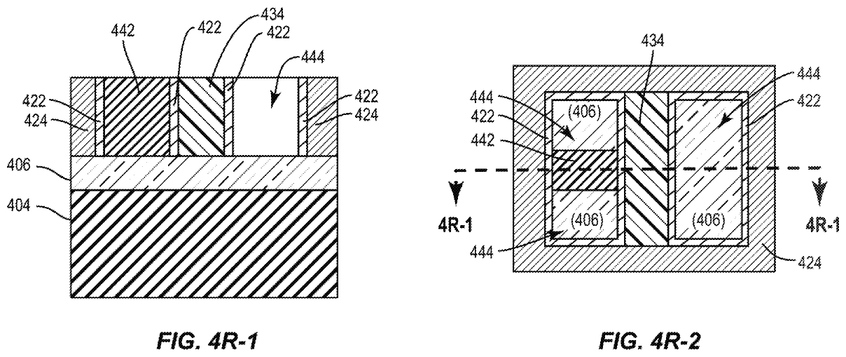

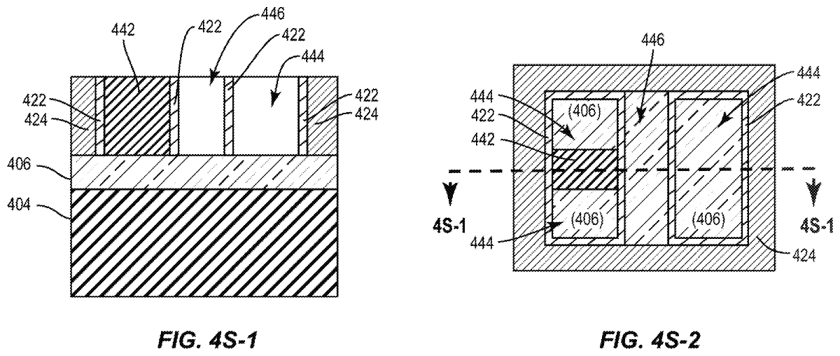

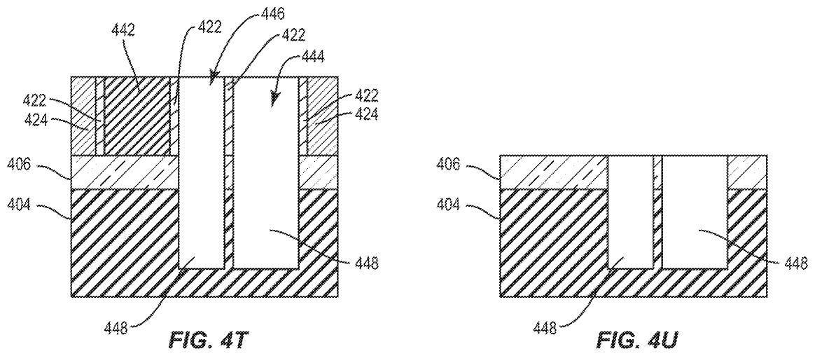

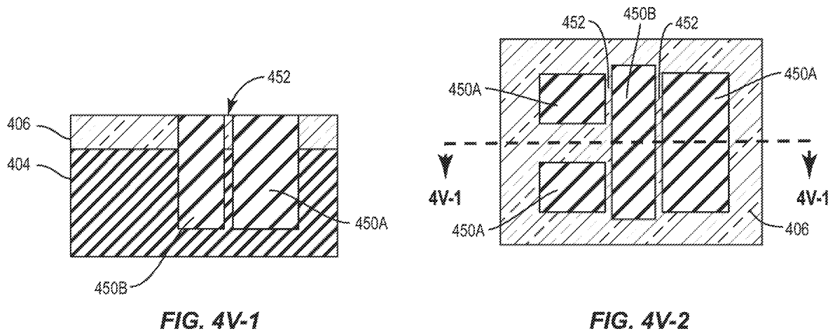

FIG. 3 is a flowchart illustrating an exemplary process for fabricating the IC 100 of FIG. 1, and in particular, for fabricating metal trenches for the IC 100 using a dual-exposure process such that the final metal trenches have a desired pitch less than 16 nm (e.g., an individual exposure has a pitch of less than 32 nm) and a certain guaranteed minimum spacing. The process 300 is set forth in FIG. 3, but the following text also references FIGS. 4A-4V-2 as illustrating the stages of the process 300, where FIGS. 4V-1 and 4V-2 show the metal trenches in place. Thus, the earlier stages of the process 300 are designed to create the structures that allow the metal trenches to be positioned as shown in FIGS. 4V-1 and 4V-2. The process 300 begins by forming a lithographic (litho) stack 400 (block 302). The litho stack 400, as illustrated in FIG. 4A is formed on top of an active element layer 402, which may include the active elements 108(1)-108(N) (not shown in FIG. 4A). The active element layer 402 may be positioned on top of the substrate 102. The litho stack 400 may include a low-k dielectric material 404, a hard layer 406 (note that sometimes this layer is also referred to as a mask in the industry literature, but for the purposes of the present disclosure, it is merely a layer), a litho material 408, and a resist 410. The litho material 408 may be a spin on carbon, spin on glass, oxide-based material, or the like as needed or desired.

With reference to FIG. 3 and FIG. 4B, a first mandrel 414 (note that this mandrel can be reused on multiple wafers) having apertures 415 is placed over the resist 410 (block 304), and the litho stack 400 is exposed to EUV radiation (block 306) from an EUV emitter 416 for a relatively short amount of time. An exemplary exposure is less than twenty mili-joules/square cm (20 mJ/cm²). This exposure is considerably less than what would normally be required in a single-exposure process. In an exemplary aspect the EUV radiation has a wavelength between 12 and 15 nm and, more particularly, at 13.5 nm. The EUV radiation interacts with the resist 410 to form “soft” portions that are able to be etched by an etchant while the portions not exposed remain “hard” and resistant to the etchant. The first mandrel 414 is removed and an etchant is applied (block 308). The etchant acts on the “soft” portions of the resist 410 and etches therethrough and down through the litho material 408 to the hard layer 406 to form first voids 418 as illustrated in FIGS. 4C-1 and 4C-2, where FIG. 4C-1 is a cross-sectional view and FIG. 4C-2 is a top view. It should be appreciated that selection of materials for the hard layer 406 will dictate what material is used for this etchant, such as hydrogen peroxide or ammonium hydroxide.

With continued reference to FIG. 3, the process 300 continues by removing the resist 410 (block 310), leaving slightly shorter voids 418′ as seen in FIGS. 4D-1 and 4D-2. The dimensions of the voids 418′ correspond to the eventual dimensions of a first set of metal trenches as modified by any cross cuts (as explained below). Thus, the dimensions of the pattern (i.e., the apertures 415) in the first mandrel 414 correspond to the dimensions of a first set of metal trenches as modified by any cross cuts. The voids 418′ are then filled with a first sacrificial material (SMA) fill 420 (block 312) as seen in FIG. 4E. The litho material 408 is then removed, such as through an etchant (block 314). This etchant is selected to remove the litho material 408 but not affect the SMA fill 420 or the hard layer 406. This removal leaves the SMA fill 420 pillars in place above the hard layer 406 as illustrated in FIG. 4F. A spacer material 422, such as conformal oxide or nitride, is grown around the SMA fill 420 (block 316) as illustrated in FIGS. 4G-1 and 4G-2. The spacer material 422 may be selected to have an etch resistance different from the SMA fill 420. It is the use of this spacer material 422 that helps ensure that there is a minimum buffer space extending outwardly around each metal trench as explained in greater detail below.

With continued reference to FIG. 3, the process 300 continues by adding a litho material 424 (block 318) back to the litho stack 400 as illustrated in FIG. 4H. The litho material 424 fills the spaces between and around the spacer material 422. A second resist 426 is added (block 320) as illustrated in FIG. 4I. In particular, the second resist 426 is placed on top of the SMA fill 420 and the litho material 424. The second resist 426 is used, as explained below, in the second EUV exposure to achieve the desired multi-patterning.

With continued reference to FIG. 3, a second mandrel 428 (again note that this mandrel can be reused on multiple wafers) having apertures 430 (only one shown) is placed over the second resist 426 (block 322). The apertures 430 of the second mandrel 428 help define a second set of metal trenches interleaved with the first set of metal trenches defined by the first mandrel 414. The second mandrel 428 is exposed to EUV radiation (block 324) from the EUV emitter 416 for a relatively short amount of time (see FIG. 4J). Again, the exposure may be for less than 20 mJ/cm². Again, this exposure makes “hard” and “soft” portions in the second resist 426. Unlike the first mandrel 414, the pattern of the apertures 430 in the second mandrel 428 does not directly define the shape of the second set of metal trenches interleaved with the first set of metal trenches. That is, the apertures 430 of the second mandrel 428 may be wider than the ultimate width of the metal trenches. For example, as illustrated in FIG. 4J, the aperture 430 has a width W1, which is wide enough to cover not just the central litho material 424A, but also portions of the spacer material 422A and 422B and the SMA fill 420 on either side of the central litho material 424A.

The second mandrel 428 is removed and an etchant is applied (block 326). The etchant is selected to provide a selective etch. Specifically, the etchant is selected to remove the “soft” portion of the second resist 426 and the central litho material 424A, but not to etch the SMA fill 420 or the spacer material 422. Thus, even though the aperture 430 exposes the width W1, the etch that subsequently occurs does not etch the SMA fill 420 or the spacer material 422.

As illustrated in FIG. 4K, after the etching of block 326, a second void 432 is present. Specifically, the central litho material 424A has been removed to create the second void 432. The second resist 426 is removed and the second void 432 is filled with a second sacrificial material (SMB) fill 434 (block 328) (see FIGS. 4L-1 and 4L-2). Again, it is worth noting that the spacer material 422 creates a buffer space between the SMA fill 420 and the SMB fill 434, in effect guaranteeing a minimum distance between the SMA fill 420 and the SMB fill 434, which in turn will create a guaranteed minimum space between the eventual metal trenches. In an exemplary aspect, the SMA fill 420 and the SMB fill 434 have different etch selectivities.

Optionally, lateral cuts (e.g., the cuts 206(1)-206(3) of FIG. 2) may be generated, which can be based on other EUV exposures or immersion-based 193i optical lithography. Such cross cuts will modify the patterns made by the first mandrel 414 and the second mandrel 428. Accordingly, the process 300 may add a third resist 436 (block 330) (see FIG. 4M). The third resist 436 is added on top of the SMA fill 420, the SMB fill 434, and the litho material 424. A cross cut 438 is made in the third resist 436 (block 332) (see FIGS. 4N-1 and 4N-2). A selective etchant is applied which does not etch the spacer material 422, but removes exposed portions of the SMA fill 420 (block 334). The removal of the SMA fill 420 creates a void 440 as illustrated in FIGS. 4O, 4P-1, and 4P-2. The third resist 436 is removed (block 336) (see FIGS. 4P-1 and 4P-2). The void 440 is then filled with an oxide 442 (block 338) (see FIGS. 4Q-1 and 4Q-2).

With continued reference to FIG. 3, an etchant is applied to remove the SMA fill 420 and create a void 444 (block 340) (see FIGS. 4R-1 and 4R-2). In a first aspect, this etchant is selective and is not operative on the SMB fill 434. A second etchant is applied to remove the SMB fill 434 and create a void 446 (block 342) (see FIGS. 4S-1 and 4S-2). In an alternate aspect, blocks 340 and 342 are combined and only a single etchant that operates on the SMA fill 420 and the SMB fill 434 is used. The process 300 has now created the structures that allow the metal trenches to be made. In particular, the structures created by the process 300 form a “mask” that is used to control a cut into the low-k dielectric material 404 that will be the space into which the metal trenches are formed.

Another etchant is used that enters the voids 444 and 446 and etches away the hard layer 406 and the low-k dielectric material 404 to form trench voids 448 (block 344) (see FIG. 4T). The trench voids 448 act as guides to form the metal trenches and thus may be referred to as trench guides. Once the trench voids 448 are formed, the oxide 442, the litho material 424, the spacer material 422, and the like are not needed. Accordingly, the process 300 continues by removing everything above the hard layer 406 (block 346) (see FIG. 4U). The trench voids 448 are then filled with metal to form metal trenches 450A interleaved with metal trenches 450B (block 348) (see FIGS. 4V-1 and 4V-2). It should be appreciated that the space 452 between the metal trenches 450A and 450B is uniform as a function of the spacer material 422.

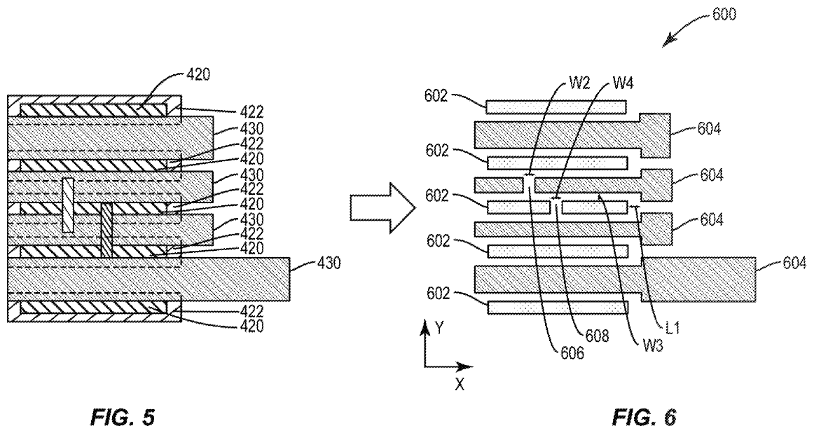

As discussed above, and illustrated in block 348 of the process 300 and FIGS. 4A-4V-2, exemplary aspects of the present disclosure provide for a buffer space around the metal trenches where the buffer space guarantees a certain minimum distance between the metal trenches. While this buffer space is created through the use of the spacer material 422, the actual metal trenches are in the low-k dielectric material 404 below the level of where the spacer material 422 used to be. Thus, while the spacer material 422 helps create artifacts which define the shape of the metal trenches, the spacer material 422 does not actually directly shape the metal trenches. FIGS. 5 and 6 provide a more detailed illustration of how the spacer material 422 forces the creation of a buffer space.

In this regard, FIG. 5 corresponds to block 324 and is in effect, an abstracted top view of FIG. 4J. The litho material 424 and the second resist 426 are not shown, but the spacer material 422 around the SMA fill 420 is. The second mandrel 428 with the apertures 430 is shown. Given the eventual etch selectivity used to etch the pattern created by the second mandrel 428, the apertures 430 may have dimensions that exceed the eventual dimensions of the metal trench. Specifically, the spacer material 422 and a portion of the SMA fill 420 may be exposed by the apertures 430. However, because of etch selectivity, the spacer material 422 will guarantee a certain minimum distance between eventual metal trenches.

Thus, in FIG. 6, metal trenches 600 are shown. The metal trenches 600 include a first set of metal trenches 602 formed by the first mandrel 414 and a second set of metal trenches 604 formed by the spacer material 422 and the second mandrel 428. Because the spacer material 422 precludes etching by the second etchant, there is a buffer zone that guarantees a certain minimum space between the first set of metal trenches 602 and the second set of metal trenches 604. Likewise, the double-exposure process lets the lateral width (y-axis) of individual ones of the metal trenches 600 be varied without changing the buffer zone. Further, the use of a double-exposure process allows cross cuts 606 and 608 to be made cleanly, without the usual rounding at the ends and without risk of inadvertently cutting an adjacent metal trench. The tip-to-tip dimensions W2 and W4 may be tightly controlled with a double-exposure process. As further illustrated in FIG. 6, the buffer zone extends outwardly not just for opposite sides in a lateral direction (both directions of the y-axis as illustrated) but also for opposite sides in a longitudinal direction (both directions of the x-axis as illustrated). Thus W3 may be equal to L1.

The ICs made using EUV patterning and methods for fabricating such ICs according to aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

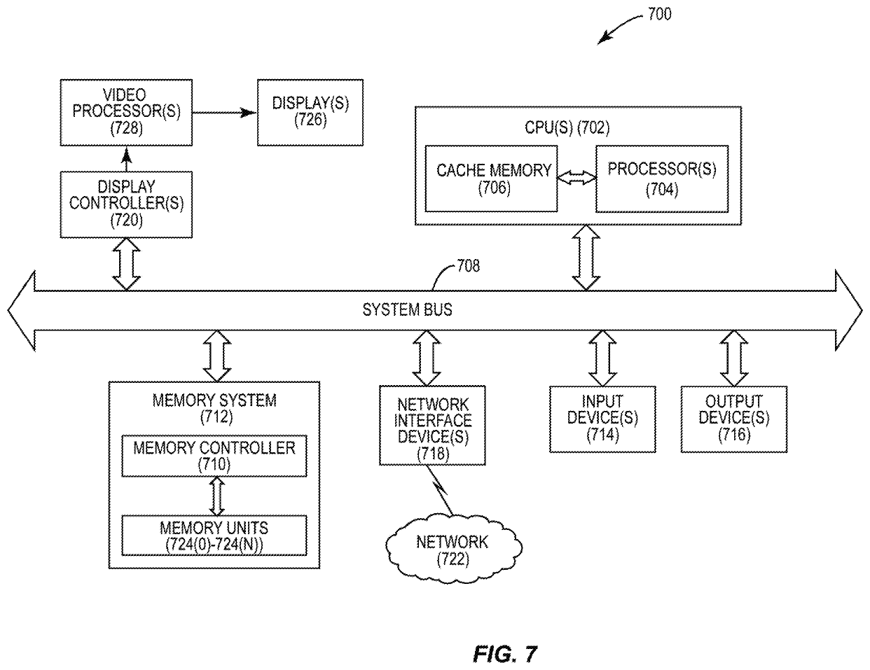

In this regard, FIG. 7 illustrates an example of a processor-based system 700 that can employ the IC 100 of FIG. 1 made through the process 300 illustrated in FIG. 3. In this example, the processor-based system 700 includes one or more central processing units (CPUs) 702, each including one or more processors 704. The CPU(s) 702 may have cache memory 706 coupled to the processor(s) 704 for rapid access to temporarily stored data. The CPU(s) 702 is coupled to a system bus 708 and can intercouple master and slave devices included in the processor-based system 700. As is well known, the CPU(s) 702 communicates with these other devices by exchanging address, control, and data information over the system bus 708. For example, the CPU(s) 702 can communicate bus transaction requests to a memory controller 710 as an example of a slave device. Although not illustrated in FIG. 7, multiple system buses 708 could be provided, wherein each system bus 708 constitutes a different fabric.

Other master and slave devices can be connected to the system bus 708. As illustrated in FIG. 7, these devices can include a memory system 712, one or more input devices 714, one or more output devices 716, one or more network interface devices 718, and one or more display controllers 720, as examples. The input device(s) 714 can include any type of input device, including, but not limited to, input keys, switches, voice processors, etc. The output device(s) 716 can include any type of output device, including, but not limited to, audio, video, other visual indicators, etc. The network interface device(s) 718 can be any devices configured to allow exchange of data to and from a network 722. The network 722 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 718 can be configured to support any type of communications protocol desired. The memory system 712 can include one or more memory units 724(0-N).

The CPU(s) 702 may also be configured to access the display controller(s) 720 over the system bus 708 to control information sent to one or more displays 726. The display controller(s) 720 sends information to the display(s) 726 to be displayed via one or more video processors 728, which process the information to be displayed into a format suitable for the display(s) 726. The display(s) 726 can include any type of display, including, but not limited to, a cathode ray tube (CRT), a liquid crystal display (LCD), a plasma display, a light emitting diode (LED) display, etc.

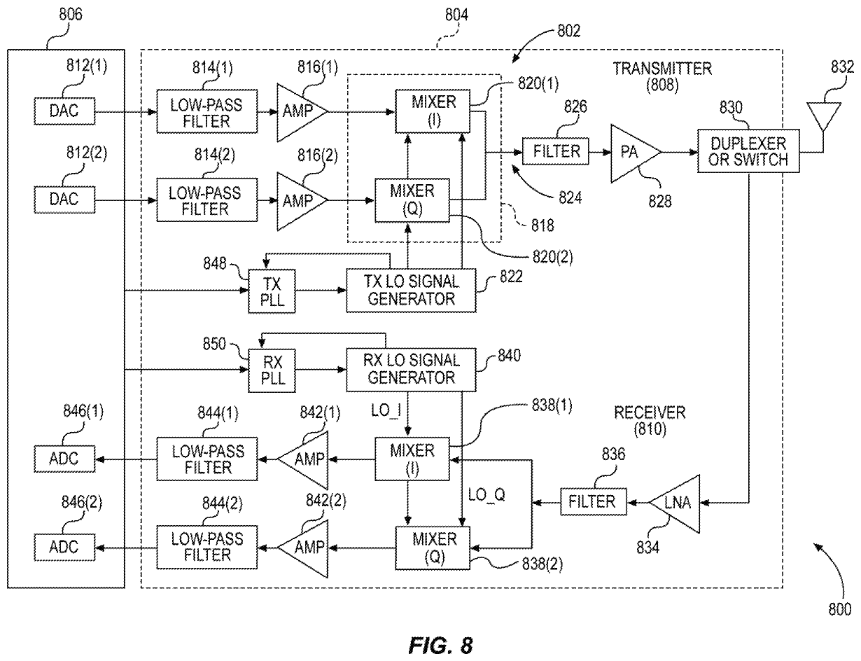

FIG. 8 illustrates an exemplary wireless communications device 800 that includes radio frequency (RF) components formed in an IC 802, wherein the IC 802 may be fabricated according to the process 300 of FIGS. 3A and 3B. The wireless communications device 800 may include or be provided in any of the above-referenced devices, as examples. As shown of FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communications systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 of FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1) and 812(2) for converting digital signals generated by the data processor 806 into the I and Q analog output signals, e.g., I and Q output currents, for further processing.

Within the transmitter 808, low-pass filters 814(1) and 814(2) filter the I and Q analog output signals, respectively, to remove undesired signals caused by the prior digital-to-analog conversion. Amplifiers (AMPs) 816(1) and 816(2) amplify the signals from the low-pass filters 814(1) and 814(2), respectively, and provide I and Q baseband signals. An upconverter 818 upconverts the I and Q baseband signals with I and Q transmit (TX) local oscillator (LO) signals through mixers 820(1) and 820(2) from a TX LO signal generator 822 to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired delivered power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1) and 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1) and 842(2) and further filtered by low-pass filters 844(1) and 844(2) to obtain I and Q analog input signals, which are provided to the data processor 806. In this example, the data processor 806 includes analog-to-digital converters (ADCs) 846(1) and 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. The devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. An integrated circuit (IC) comprising:
a substrate;
an active element disposed on a first side of the substrate; and
a metal layer disposed above the active element on the first side of the substrate;
wherein the metal layer comprises a metal trench, wherein the metal trench comprises a buffer zone and the buffer zone has a uniform outward dimension on two opposite sides of the metal trench.

2. The IC of claim 1, wherein the metal trench comprises a plurality of metal trenches, each metal trench within the plurality of metal trenches separated from others of the plurality of metal trenches by a corresponding buffer zone.

3. The IC of claim 2, wherein at least one of the plurality of metal trenches comprises a power rail.

4. The IC of claim 2, wherein at least one of the plurality of metal trenches comprises a ground rail.

5. The IC of claim 3, wherein at least one other of the plurality of metal trenches comprises an interconnection between the active element and a second active element disposed on the first side of the substrate and the power rail has a different lateral dimension than the interconnection.

6. The IC of claim 1, wherein the uniform outward dimension comprises a dimension corresponding to a longitudinal axis of the metal trench.

7. The IC of claim 1, wherein the uniform outward dimension comprises a dimension corresponding to a lateral axis of the metal trench.

8. The IC of claim 1, wherein the buffer zone comprises a spacer artifact.

9. The IC of claim 2, wherein at least two of the plurality of metal trenches are parallel.

10. The IC of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

11. An integrated circuit (IC) comprising:
a means for supporting active elements;
a means for performing a function disposed on a first side of the means for supporting the active elements; and
a metal layer disposed above the means for performing the function on the first side of the means for supporting the active elements;
wherein the metal layer comprises a metal trench, wherein the metal trench comprises a buffer zone and the buffer zone has a uniform outward dimension on two opposite sides of the metal trench.

12-22. (canceled)
